(19) United States
(12) Patent Application Publication
(10) Pub. No.: US 2008/0223436 A1
(43) Pub. Date: Sep. 18, 2008

(54) Back reflector for use in photovoltaic device

(75) Inventors: Willem den Boer, Brighton, MI (US); Yiwei Lu, Ann Arbor, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/724,326

(22) Filed: Mar. 15, 2007

(51) Int. Cl. H01L 31/0216

(52) U.S. Cl. 136/256

(57) ABSTRACT

This invention relates to a photovoltaic device including a back reflector. In certain example embodiments, the back reflector includes a metallic based reflective layer provided on an interior surface of a rear glass substrate of the photovoltaic device. In certain example embodiments, the interior surface of the rear glass substrate is textured so that the reflector layer deposited thereon is also textured so as to provide desirable reflective characteristics. The rear glass substrate and reflector thereon are laminated to the interior surface of a front glass substrate of the photovoltaic device, with an active semiconductor film and electrode(s) therebetween, in certain example embodiments.

This invention relates to a photovoltaic device including a back reflector. In certain example embodiments of this invention, the back reflector includes a metallic based reflective layer provided on an interior surface of a rear glass substrate of the photovoltaic device. In certain example embodiments, the interior surface of the rear glass substrate is textured so that the reflector layer deposited thereon is also textured so as to provide desirable reflective characteristics. The rear glass substrate and reflector thereon are laminated to the interior surface of a front glass substrate of the photovoltaic device, with an active semiconductor film and electrode(s) therebetween, in certain example embodiments.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon (a-Si) photovoltaic devices, for example, include (moving away from the sun or light source) a front substrate, a front electrode or contact, an active semiconductor film or absorber, and a dual-layer rear electrode or contact. Typically, the transparent front electrode is made of a pyrolytic transparent conductive oxide (TCO) such as fluorine doped tin oxide, or zinc oxide, formed on the front substrate. The dual-layer rear electrode or contact often includes a first TCO layer closest to and contacting the semiconductor and a second reflective layer of silver immediately adjacent thereto.

Conventionally, the interior surface of the front electrode is often textured, which in turn is used to cause the semiconductor film and rear electrode or contact to also be textured moving away from the front electrode. The texturing is at a microscopic level and leads to scattering in the films. The purpose of the texture in the rear electrode or contact is to better trap long wavelength light in the 600-800 nm range in the semiconductor film and enhance photovoltaic efficiency.

Unfortunately, photovoltaic devices (e.g., solar cells) such as that discussed above suffer from one or more of the following problems. First, the front electrode (e.g., TCO) must be textured which may involve an additional step such as a texture etch. Second, there may be an impact on reliability of the semiconductor (e.g., a-Si) when it follows the texture of the front electrode, potentially leading to shorts, weak points, and/or other defects in the semiconductor film—in particular when it is very thin. Third, the materials from which the front electrode are made may be limited as certain alternative types of front electrode materials tend to realize an increase in resistance when they are textured and not smooth. Fourth, the front electrode TCO needs to be relatively thick (e.g., 400-800 nm) to obtain acceptable sheet resistance, thereby increasing costs and lowering manufacturing throughput.

Thus, it will be appreciated that there exists a need in the art for an improved photovoltaic device that can solve or address one or more of the aforesaid problems.

In certain example embodiments of this invention, a photovoltaic device is provided with an improved back reflector structure. In certain example embodiments of this invention, the back reflector includes a metallic based reflective layer provided on an interior surface of a rear glass substrate of the photovoltaic device. In certain example embodiments, the interior surface of the rear glass substrate is textured so that the reflector layer deposited thereon is also textured so as to provide desirable reflective characteristics. The rear glass substrate and reflector thereon are laminated to the interior surface of a front glass substrate of the photovoltaic device, with an active semiconductor film and electrode(s) therebetween, in certain example embodiments.

Thus, in certain example embodiments of this invention, the front electrode need not be textured (although it may be in certain instances), the semiconductor film need not be textured (although it may be in certain instances), the front electrode may realize a relatively thin thickness (although it may be thick in certain instances), and/or options are available for alternative front electrode materials. Accordingly, one or more of the above-listed problems may be addressed and solved.

In certain example embodiments of this invention, optionally, the front electrode of the photovoltaic device may be comprised of a multilayer coating including at least one transparent conductive oxide (TCO) layer (e.g., of or including a material such as tin oxide, zinc oxide, or the like) and at least one conductive substantially metallic IR reflecting layer (e.g., based on silver, gold, or the like). In certain example instances, the multilayer front electrode coating may include a plurality of TCO layers and/or a plurality of conductive substantially metallic IR reflecting layers arranged in an alternating manner in order to provide for reduced visible light reflections, increased conductivity, increased IR reflection capability, and so forth. In certain example embodiments of this invention, such a multilayer front electrode coating may be flat and be designed to realize one or more of the following advantageous features: (a) reduced sheet resistance (R,) and thus increased conductivity and improved overall photovoltaic module output power; (b) increased reflection of infrared (IR) radiation thereby reducing the operating temperature of the photovoltaic module so as to increase module output power; (c) reduced reflection and increased transmission of light in the region(s) of from about 450-700 nm and/or 450-600 nm which leads to increased photovoltaic module output power; (d) reduced total thickness of the front electrode coating which can reduce fabrication costs and/or time; and/or (e) an improved or enlarged process window in forming the TCO layer(s) because of the reduced impact of the TCO's conductivity on the overall electric properties of the module given the presence of the highly conductive substantially metallic layer(s). In certain example embodiments, such a multi-layer front electrode may optionally be used in combination with the back reflector structure discussed above because the back reflector structure allows for a thinner front electrode to be used that need not be textured.

While the back reflector embodiment of this invention may be used in combination with the multi-layer front electrode embodiment in certain instances, this invention is not so limited. For example, in certain example embodiments of this invention, a conventional TCO (textured or non-textured) or the like may be used as the front electrode in a photovoltaic device using the back reflector embodiment of this invention.

In certain example embodiments of this invention, there is provided a photovoltaic device comprising: a front glass substrate and a rear glass substrate; an electrically conductive and substantially transparent front electrode; an active semiconductor film located so that the front electrode is provided between at least the semiconductor film and the front glass substrate; a conductive back contact; a back reflector formed on a textured surface of the rear glass substrate, the back reflector having a textured reflective surface and being located between at least the rear glass substrate and the semiconductor film; and an electrically insulating polymer inclusive adhesive layer laminating at least the back reflector and rear glass substrate to the front glass substrate with at least the front electrode, the semiconductor film and the conductive back contact therebetween.

In other example embodiments of this invention, there is provided a photovoltaic device comprising: a front substrate and a rear substrate; an electrically conductive and substantially transparent front electrode; an active semiconductor film located so that the front electrode is provided between at least the semiconductor film and the front substrate; a back reflector formed on a textured surface of the rear substrate, the back reflector having a textured reflective surface and being located between at least the rear substrate and the semiconductor film; and wherein the back reflector is laminated to and electrically insulated from at least the semiconductor film.

### BRIEF DESCRIPTION OF THE DRAWINGS

FIG. 1 is a cross sectional view of an example photovoltaic device according to an example embodiment of this invention.

FIG. 2 is an enlarged cross-sectional view of the back reflector of the photovoltaic device of FIG. 1 (or any of FIGS. 3-5).

FIG. 3 is a cross sectional view of an example photovoltaic device according to another example embodiment of this invention.

FIG. 4 is a cross sectional view of an example photovoltaic device according to another example embodiment of this invention.

FIG. 5 is a cross sectional view of an example photovoltaic device according to another example embodiment of this invention.

FIG. 6 is a refractive index (n) vs. wavelength (nm) graph illustrating the refractive index of example materials in an example photovoltaic device according to an example embodiment of this invention.

FIG. 7 is an extinction coefficient (k) vs. wavelength (nm) graph illustrating the extinction coefficient of example materials in an example photovoltaic device according to an example embodiment of this invention.

### DETAILED DESCRIPTION OF EXAMPLE EMBODIMENTS OF THE INVENTION

Referring now more particularly to the figures in which like reference numerals refer to like parts/layers in the several views.

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, the semiconductor film includes a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, single or tandem thin-film solar cells, CdS and/or CdTe photovoltaic devices, polysilicon and/or microcrystalline Si photovoltaic devices, and the like.

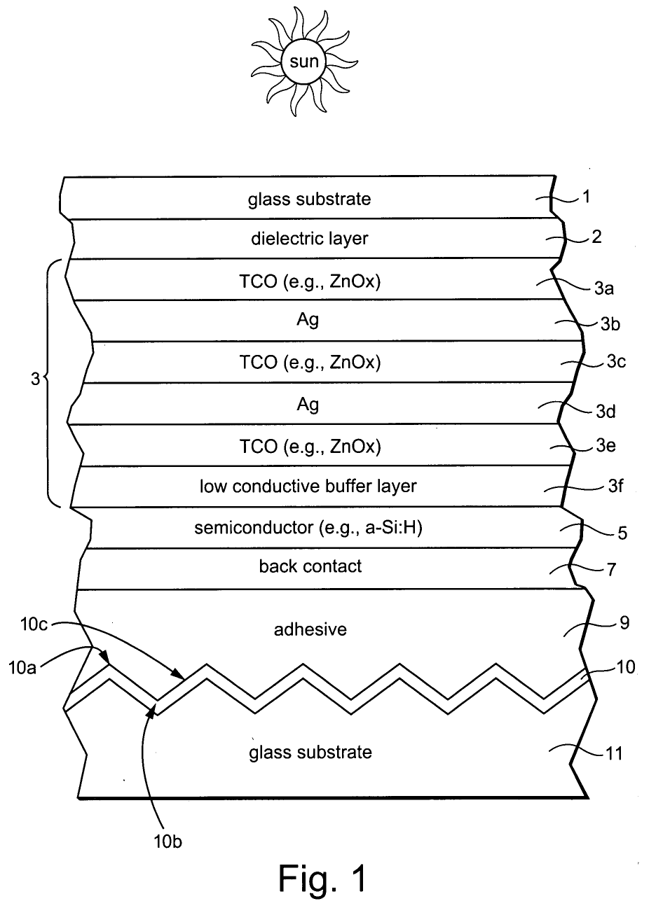

In certain example embodiments of this invention, a photovoltaic device is provided with an improved back reflector structure. In certain example embodiments of this invention (e.g., see FIGS. 1-5), the back reflector includes a metallic based reflective layer 10 provided on an interior surface of a rear glass substrate 11 of the photovoltaic device. In certain example embodiments, the interior surface of the rear glass substrate 11 is textured so that the reflector layer 10 deposited thereon is also textured so as to provide desirable reflective characteristics. The rear glass substrate 11 and reflector 10 thereon are laminated to the interior surface of a front glass substrate of the photovoltaic device via an adhesive layer 9, with an active semiconductor film 5 and electrode(s) 3 and/or 7 therebetween, in certain example embodiments. A white Lambertian or quasi-Lambertian reflector may be provided in certain example embodiments.

Because of this improved back reflector structure, the front electrode 3 need not be textured (although it may be in certain instances), the semiconductor film 5 need not be textured (although it may be in certain instances), the front electrode 3 may realize a relatively thin thickness (although it may be thick in certain instances), and/or options are available for alternative front electrode materials. Accordingly, one or more of the above-listed problems may be addressed and solved. Because the front electrode 3 and semiconductor film 5 may be smooth or substantially smooth, the reliability and/or manufacturing yield of the device can be improved, and possibly thinner i-type a-Si layers may be used in certain example instances. The deposition rate of intrinsic a-Si is quite low (e.g., less than 0.5 nm/sec) and is the rate and throughput limiting step in a-Si photovoltaic manufacturing. Moreover, the smooth nature of front electrode 3 allows a multi-layer coating including at least one silver layer or the like to be used to form the front electrode 3 in certain example instances; such coatings may have an improved (e.g., lower) sheet resistance while at the same time maintaining high transmission in the part of the spectrum in which the photovoltaic device is sensitive (e.g., 350 to 750, 350 to 800 nm, or possibly up to about 1100 nm for certain types). Low sheet resistance is advantageous in that it allows for less dense laser scribing and may lead to lower scribe losses. Furthermore, the total thickness of such a multilayer front electrode 3 may be less than that of a conventional TCO front electrode in certain example non-limiting instances, which can reduce the cost of the product and increase throughput.

FIG. 1 is a cross sectional view of a photovoltaic device according to an example embodiment of this invention. The photovoltaic device includes transparent front glass substrate 1, optional dielectric layer(s) 2, multilayer front electrode 3, active semiconductor film 5 of or including one or more semiconductor layers (such as pin, pn, pinpin tandem layer stacks, or the like), back electrode/contact 7 which may be of a TCO or a metal, an electrically insulating polymer based and/or polymer inclusive encapsulant or adhesive 9 of a material such as ethyl vinyl acetate (EVA), polyvinyl butyral (PVB), or the like, back reflector 10, and rear substrate 11 of a material such as glass. Of course, other layer(s) which are not shown may also be provided in the device. Front glass substrate I and/or rear superstrate (substrate) 11 may be made of soda-lime-silica based glass in certain example embodiments of this invention; and front glass substrate 1 may have low iron content and/or an antireflection coating (not shown) thereon to optimize transmission in certain example instances. While substrates 1, 11 may be of glass in certain example embodiments of this invention, other materials such as quartz or the like may instead be used for substrate(s) 1 and/or 11. Glass substrate(s) 1 and/or 11 may or may not be thermally tempered in certain example embodiments of this invention. Additionally, it will be appreciated that the word “on” as used herein covers both a layer being directly on and indirectly on something, with other layers possibly being located therebetween.

The interior surface of the rear glass substrate 11 (e.g., cover glass) is macroscopically textured as shown in the figures, and the reflector 10 is deposited (e.g., via sputtering or the like) on the textured surface of the substrate 11. The reflective layer 10 may be made of a metallic reflective material such as Ag, Al or the like in certain example embodiments of this invention. Reflector 10 reflects significant amounts of light in the 500-800 nm, and/or 600-800 nm wavelength range, thereby permitting such light to be trapped in the semiconductor film 5 to enhance the photovoltaic efficiency of the device. Reflector 10 is electrically insulated from the back electrode or contact 7 and/or semiconductor 5, by insulating adhesive layer 9 in certain example embodiments of this invention; thus, reflector 10 does not function as an electrode in certain example embodiments of this invention.

In certain example embodiments, the macroscopically textured interior surface of glass substrate 11 may have any suitable pattern, such as a pyramid pattern obtained by rolling or the like. This textured pattern may have a periodicity of from about 100 μm to 1 mm (more preferably from about 250 to 750 μm) in certain example embodiments, depending on the capabilities of the glass patterning line. Other possible patterns for the interior surface of glass 11 include triangular or sawtooth trough patterns and, in general, any combination of slanted patterns which maximizes or substantially maximizes multiple internal reflections. In certain example embodiments, rear glass substrate 11 with reflector 10 thereon are laminated to the interior surface of front glass substrate 1 via adhesive layer 9. In certain example embodiments, polymer based adhesive layer 9 has a refractive index (n) of from about 1.8 to 2.2, more preferably from about 1.9 to 2.1, with an example being about 2.0, for purposes of optical matching—possibly with the rear electrode/contact 7 when it is of a TCO having a similar refractive index.

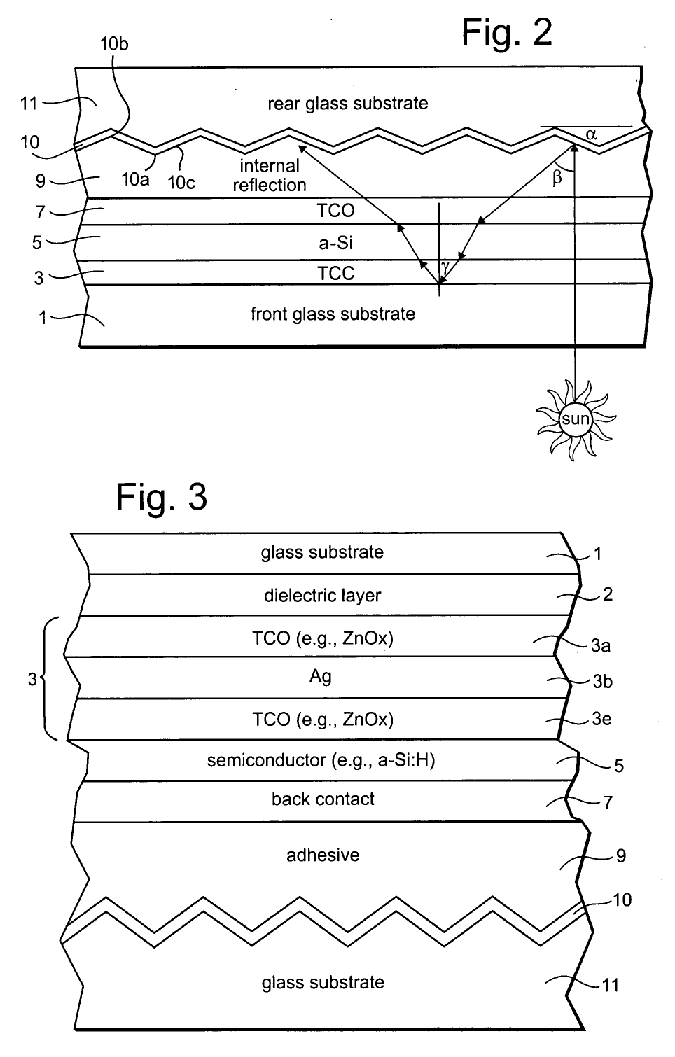

FIG. 2 is an enlarged cross-sectional view of the back reflector of the photovoltaic device of FIG. 1 (or any of FIGS. 3-5). FIG. 2 illustrates the front electrode as a transparent conductive coating (TCC) for purposes of simplicity, and the rear electrode or contact 7 as a TCO (transparent conductive oxide) for purposes of example only. The reflective layer 10 includes peaks 10a, valleys 10b, and inclined portions 10c connecting the peaks and valleys.

Referring to FIGS. 1-2, it can be seen that incident light from the sun makes its way first through front substrate 1 and front electrode 3, and into semiconductor film 5. Some of this light proceeds through semiconductor film 5, rear electrode or contact 7, and polymer based adhesive or laminating layer 9, and is reflected by reflector 10 which is provided on the interior textured surface of the rear substrate 11. Assume, for purposes of example and understanding, that for monochromatic light under normal incidence, we can calculate the condition for total internal reflection (TIR) as follows. If the angle of the inclined portion(s) of the reflector 10 is α as shown in FIG. 2, the light is reflected in the laminate under angle β=2α. Assuming for purposes of example only that the refractive index (n) of the front electrode 3 is the same as the laminating adhesive 9 (e.g., n=2), i.e., γ=β, the critical angle for TIR is: γ=arcsin(n_{glass}/n_{front electrode})=50 degrees. Therefore, TIR occurs when α>25 degrees in this example instance. Thus, in certain example embodiments of this invention, the reflective layer 10 includes inclined portions 10c which form an angle(s) α with the plane (and/or rear surface) of the rear substrate 11, where α is at least about 25 degrees, more preferably from about 25-40 degrees, even more preferably from about 25-35 or 25-30 degrees. Causing this angle α to be within such a range is advantageous in that more light is kept in the cell (i.e., in the semiconductor 5 for conversion to current) so that the efficiency of the photovoltaic device is improved.

Dielectric layer 2 is optional and may be of any substantially transparent material such as a metal oxide and/or nitride which has a refractive index of from about 1.5 to 2.5, more preferably from about 1.6 to 2.5, more preferably from about 1.6 to 2.2, more preferably from about 1.6 to 2.0, and most preferably from about 1.6 to 1.8. However, in certain situations, the dielectric layer 2 may have a refractive index (n) of from about 2.3 to 2.5. Example materials for dielectric layer 2 include silicon oxide, silicon nitride, silicon oxynitride, zinc oxide, tin oxide, titanium oxide (e.g., TiO₂), aluminum oxynitride, aluminum oxide, or mixtures thereof. Dielectric layer 2 functions as a barrier layer in certain example embodiments of this invention, to reduce materials such as sodium from migrating outwardly from the glass substrate 1 and reaching the front electrode and/or semiconductor. Moreover, dielectric layer 2 is material having a refractive index (n) in the range discussed above, in order to reduce visible light reflection and thus increase transmission of light in the part of the spectrum in which the photovoltaic device is sensitive, through the coating and into the semiconductor 5 which leads to increased photovoltaic module output power.

In certain example embodiments of this invention (e.g., see FIG. 1), a multilayer front electrode 3 may be used in the photovoltaic device. The multilayer front electrode 3 shown in FIG. 1 is provided for purposes of example only and is not intended to be limiting, and includes from the glass substrate 1 moving toward the semiconductor film 5, first transparent conductive oxide (TCO) layer 3a, first conductive substantially metallic IR reflecting layer 3b, second TCO layer 3c, second conductive substantially metallic IR reflecting layer 3d, third TCO layer 33, and optional buffer layer 3f. Optionally, layer 3a may be a dielectric layer instead of a TCO in certain example instances and serve as a seed layer for the layer 3b. This multilayer film makes up the front electrode 3 in certain example embodiments of this invention. Of course, it is possible for certain layers of electrode 3 to be removed in certain alternative embodiments of this invention (e.g., one or more of layers 3a, 3c, 3d and/or 3e may be removed), and it is also possible for additional layers to be provided in the multilayer electrode 3. Front electrode 3 may be continuous across all or a substantial portion of glass substrate 1 and may be flat in certain example instances (i.e., not textured), or alternatively may be patterned into a desired design (e.g., stripes), in different example embodiments of this invention. Each of layers/films 1-3 is substantially transparent in certain example embodiments of this invention.

In the front electrode 3, first and second conductive substantially metallic IR reflecting layers 3b and 3d may be of or based on any suitable IR reflecting material such as silver, gold, or the like. These materials reflect significant amounts of IR radiation, thereby reducing the amount of IR which reaches the semiconductor film 5. Since IR increases the temperature of the device, the reduction of the amount of IR radiation reaching the semiconductor film 5 is advantageous in that it reduces the operating temperature of the photovoltaic module so as to increase module output power. Moreover, the highly conductive nature of these substantially metallic layers 3b and/or 3d permits the conductivity of the overall electrode 3 to be increased. In certain example embodiments of this invention, the multilayer electrode 3 has a sheet resistance of less than or equal to about 12 ohms/square, more preferably less than or equal to about 9 ohms/square, and even more preferably less than or equal to about 7 or 6 ohms/square. Again, the increased conductivity (same as reduced sheet resistance) increases the overall photovoltaic module output power, by reducing resistive losses in the lateral direction in which current flows to be collected at the edge of cell segments. It is noted that first and second conductive substantially metallic IR reflecting layers 3b and 3d (as well as the other layers of the electrode 3) are thin enough so as to be substantially transparent to light in the part of the spectrum in which the photovoltaic device is sensitive. In certain example embodiments of this invention, first and/or second conductive substantially metallic IR reflecting layers 3b and/or 3d are each from about 3 to 12 nm thick, more preferably from about 5 to 10 nm thick, and most preferably from about 5 to 8 nm thick. In embodiments where one of the layers 3b or 3d is not used, then the remaining conductive substantially metallic IR reflecting layer may be from about 3 to 18 nm thick, more preferably from about 5 to 12 nm thick, and most preferably from about 6 to 11 nm thick in certain example embodiments of this invention. These thicknesses are desirable in that they permit the layers 3b and/or 3d to reflect significant amounts of longer wavelength IR radiation, while at the same time being substantially transparent to visible radiation and near IR which is permitted to reach the semiconductor 5 to be transformed by the photovoltaic device into electrical energy. The highly conductive IR reflecting layers 3b and 3d attribute to the overall conductivity of the electrode 3 much more than the TCO layers; this allows for expansion of the process window(s) of the TCO layer(s) which has a limited window area to achieve both high conductivity and transparency.

First, second, and third TCO layers 3a, 3c and 3e, respectively, may be of any suitable TCO material including but not limited to conductive forms of zinc oxide, zinc aluminum oxide, tin oxide, indium-tin-oxide, indium zinc oxide (which may or may not be doped with silver), or the like. These layers are typically substoichiometric so as to render them conductive as is known in the art. For example, these layers are made of material(s) which gives them a sheet resistance of no more than about 30 ohms/square (more preferably no more than about 25, and most preferably no more than about 20 ohms/square) when at a non-limiting reference thickness of about 400 nm. One or more of these layers may be doped with other materials such as nitrogen, fluorine, aluminum or the like in certain example instances, so long as they remain conductive and substantially transparent to visible light. In certain example embodiments of this invention, TCO layers 3c and/or 3e are thicker than layer 3a (e.g., at least about 5 nm, more preferably at least about 10, and most preferably at least about 20 or 30 nm thicker). In certain example embodiments of this invention, TCO layer 3a is from about 3 to 80 nm thick, more preferably from about 5-30 nm thick, with an example thickness being about 10 nm. Optional layer 3a is provided mainly as a seeding layer for layer 3b and/or for antireflection purposes, and its conductivity is not as important as that of layers 3b-3e. In certain example embodiments of this invention, TCO layer 3c is from about 20 to 150 nm thick, more preferably from about 40 to 120 nm thick, with an example thickness being about 74-75 nm. In certain example embodiments of this invention, TCO layer 3e is from about 20 to 180 nm thick, more preferably from about 40 to 130 nm thick, with an example thickness being about 94 or 115 nm. In certain example embodiments, part of layer 3e, e.g., from about 1-25 nm or 5-25 nm thick portion, at the interface between layers 3e and 5 may be replaced with a low conductivity high refractive index (n) film 3f such as titanium oxide to enhance transmission of light as well as to reduce back diffusion of generated electrical carriers; in this way performance may be further improved.

In certain example embodiments of this invention, the photovoltaic device may be made by providing glass substrate 1, and then depositing (e.g., via sputtering or any other suitable technique) multilayer electrode 3 on the substrate 1. Thereafter the structure including substrate 1 and front electrode 3 is coupled with the rest of the device in order to form the photovoltaic device shown in FIG. 1. For example, the semiconductor layer 5 and back electrode contact 7 may then be formed over the front electrode on substrate 1, with the rear substrate 11 and reflector 10 then being laminated to the front substrate 1 via adhesive 9.

The alternating nature of the TCO layers 3a, 3c and/or 3e, and the conductive substantially metallic IR reflecting layers 3b and/or 3d, is also advantageous in that it allows one, two, three, four or all of the following advantages to be realized: (a) reduced sheet resistance (Rₛ) of the overall electrode 3 and thus increased conductivity and improved overall photovoltaic module output power; (b) increased reflection of infrared (IR) radiation by the electrode 3 thereby reducing the operating temperature of the semiconductor 5 portion of the photovoltaic module so as to increase module output power; (c) reduced reflection and increased transmission of light in the part of the spectrum in which the photovoltaic device is sensitive (e.g., 350 to 750, 350 to 800 nm, or possibly up to about 1100 nm for certain types) by the front electrode 3 which leads to increased photovoltaic module output power; (d) reduced total thickness of the front electrode coating 3 which can reduce fabrication costs and/or time; and/or (e) an improved or enlarged process window in forming the TCO layer(s) because of the reduced impact of the TCO's conductivity on the overall electric properties of the module given the presence of the highly conductive substantially metallic layer(s). Additional details of example front electrodes 3 may be found in pending Ser. No. 11/591,668, filed Nov. 2, 2006, the entire disclosure of which is hereby incorporated herein by reference.

Alternatively, the front electrode 3 may be made of a single layer of TCO such as tin oxide, zinc oxide, ITO, or the like, in certain other example embodiments of this invention. Such TCO front electrodes 3 may be of any suitable thickness.

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. The p-type a-Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, hydrogenated microcrystalline silicon, or other suitable material(s) in certain example embodiments of this invention. It is possible for the active region 5 to be of a double-junction or triple-junction type in alternative embodiments of this invention. CdTe and/or CdS may also be used for semiconductor film 5 in alternative embodiments of this invention.

Back contact or electrode 7 may be of any suitable electrically conductive material. The phrase “back contact” as used herein means a conductive layer, continuous or discontinuous, that is provided on a rear side of the semiconductor film and which may or may not function as an electrode. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type (e.g., similar to that shown for the front electrode in FIGS. 1, 3 and/or 4) in different instances. Moreover, the back contact/electrode 7 may include both a TCO portion and a metal portion in certain instances. The back contact 7 may be formed via sputtering or the like in certain example embodiments of this invention.

The reflective layer 10 is separated from the back electrode or contact 7 by adhesive or laminating layer 9. Reflective layer 10 of the back reflector may be of a light reflective material such as silver, molybdenum, platinum, steel, iron, niobium, titanium, chromium, bismuth, antimony, aluminum, or mixtures thereof, in certain example embodiments of this invention. The back reflector 10 may be formed via sputtering or any other suitable technique in different example embodiments of this invention. An example adhesive or laminating material(s) for layer 9 is EVA or PVB. However, other materials such as Tedlar type plastic, Nuvasil type plastic, Tefzel type plastic or the like may instead be used for layer 9 in different instances. In certain example embodiments, the adhesive 9 has a refractive index (n) of from about 1.8 to 2.2, more preferably about 2.0. If the refractive index is too low, there may be insufficient total or partial internal reflection. The back reflector, in certain example embodiments, may have texturing on the light receiving surface thereof from etching or from patterning such as roll patterning or the like, in order to enhance reflectivity.

FIG. 3 is a cross sectional view of a photovoltaic device according to another example embodiment of this invention. The FIG. 3 embodiment is the same as the FIG. 1-2 embodiment except that layers 3c, 3d and 3f are omitted in the FIG. 3 embodiment.

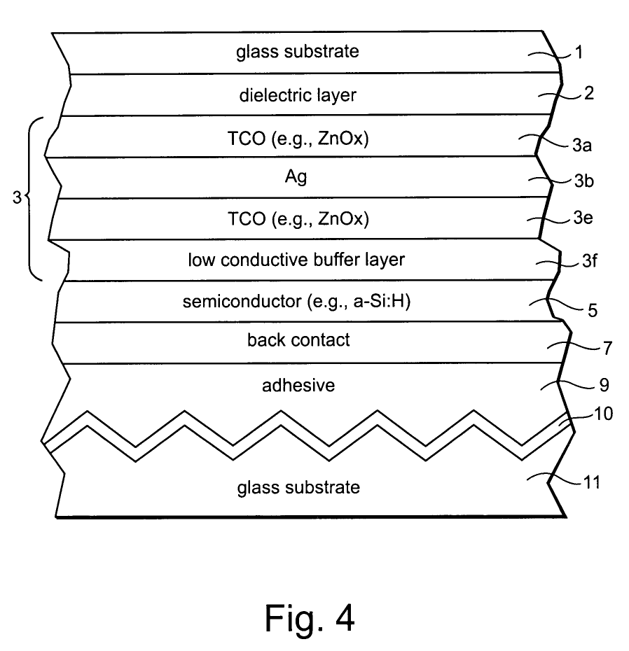

FIG. 4 is a cross sectional view of a photovoltaic device according to another example embodiment of this invention. The FIG. 4 embodiment is the same as the FIG. 1-2 embodiment except that layers 3c and 3d of the front electrode 3 are omitted in the FIG. 4 embodiment.

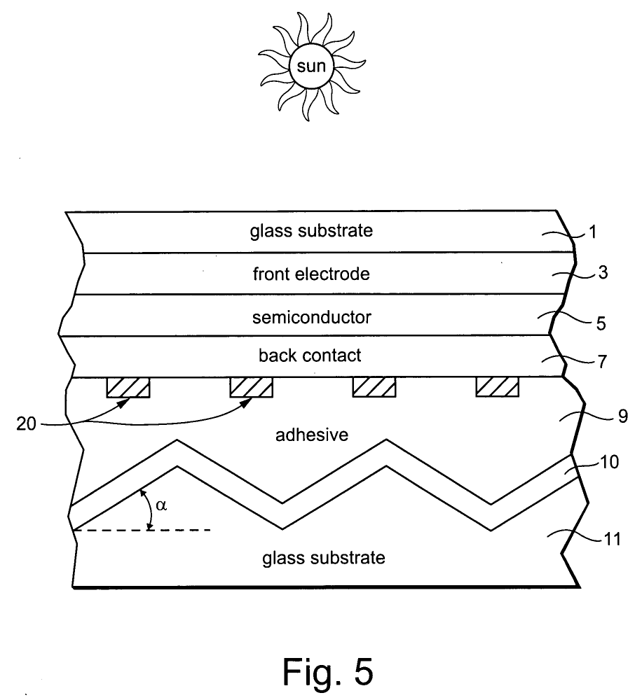

FIG. 5 is a cross sectional view of a photovoltaic device according to another example embodiment of this invention. In the FIG. 5 embodiment, the glass substrate 1, front electrode 3, semiconductor film 5, back electrode/contact 7, adhesive 9, reflector 10 and substrate 11 have been described previously (see above). The front electrode 3 may be a TCO layer, or alternatively a multi-layer design as discussed above, in different example embodiments of this invention. Moreover, in the FIG. 5 embodiment, a conductive grid 20 of silver, aluminum, or the like is provided on the rear surface of the back electrode or contact 7. In situations where a TCO such as tin oxide, ITO, zinc oxide, or the like is used for the back electrode/contact 7, its resistance can be reduced by a conductive grid 20 (e.g., formed using Ag and/or Al paste, or the like) screen printed or otherwise formed on the rear surface of the electrode/contact 7. Since this grid 20 is on the back, it will have no significant impact on strongly absorbed blue and green light, and only a minor impact on overall absorption of solar light by the semiconductor film 5. The grid 20 can also increase module efficiency by reducing lateral resistive losses. In certain example embodiments, the grid 20 may be made up of a plurality of elongated stripes which may or may not criss-cross in different example instances.

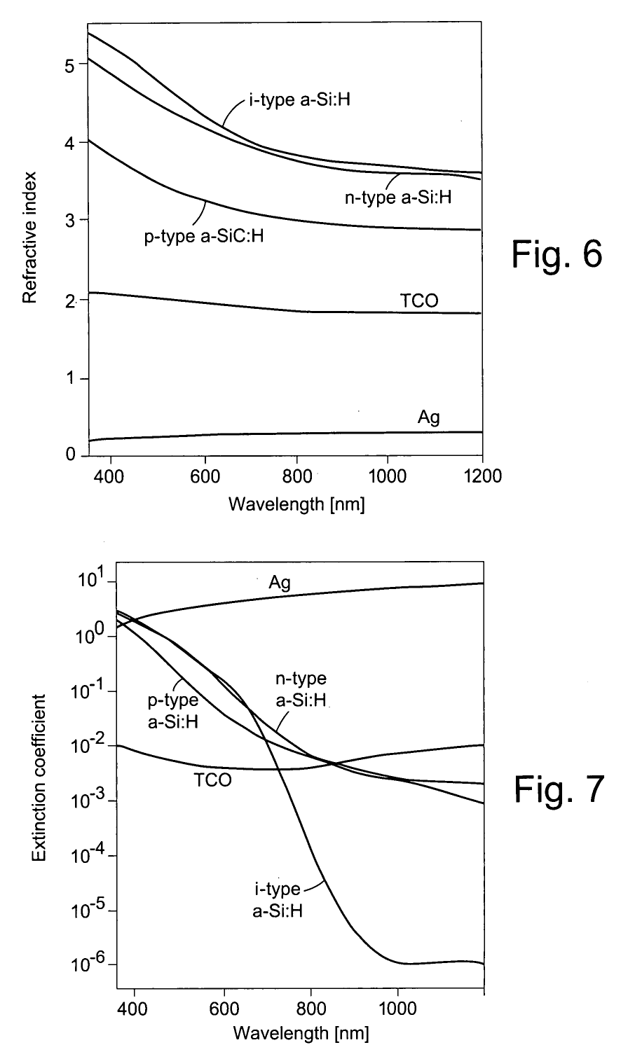

FIG. 6 is a refractive index (n) vs. wavelength (nm) graph illustrating the refractive index of example materials in an example a-Si solar cell according to an example embodiment of this invention; and FIG. 7 is an extinction coefficient (k) vs. wavelength (nm) graph illustrating the extinction coefficient of example materials in the example a-Si solar cell. FIGS. 6-7 show the refractive indices and extinction coefficients as a function of wavelength of example materials in an a-Si solar cell. In certain example embodiments of this invention, these n and k values are taken into account in the optimization over the relevant part of the solar spectrum for the relevant range of incident angles. The adhesive layer 9 and back electrode or contact 7 do not have to have very low extinction coefficients for this back reflector approach to be effective, in certain example embodiments of this invention. It is noted that the thicknesses and refractive indices of the layer(s) of the front electrode 3 may also be optimized in certain example embodiments of this invention.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A photovoltaic device comprising:
a front glass substrate and a rear glass substrate;
an electrically conductive and substantially transparent front electrode;
an active semiconductor film located so that the front electrode is provided between at least the semiconductor film and the front glass substrate;
a conductive back contact;
a back reflector formed on a textured surface of the rear glass substrate, the back reflector having a textured reflective surface and being located between at least the rear glass substrate and the semiconductor film; and
an electrically insulating polymer inclusive adhesive layer laminating at least the back reflector and rear glass substrate to the front glass substrate with at least the front electrode, the semiconductor film and the conductive back contact therebetween.

2. The photovoltaic device of claim 1, wherein the back reflector is electrically insulated from the back contact via at least the polymer inclusive adhesive layer.

3. The photovoltaic device of claim 1, wherein the conductive back contact comprises a transparent conductive oxide.

4. The photovoltaic device of claim 1, wherein the polymer inclusive adhesive layer comprises PVB and/or EVA.

5. The photovoltaic device of claim 1, wherein the textured reflective surface of the back reflector comprises peaks, valleys and inclined portions connecting the peaks and valleys, and wherein major surfaces of at least some of the inclined portions form an angle α of at least about 25 degrees with the plane and/or rear surface of the rear glass substrate.

6. The photovoltaic device of claim 1, wherein viewed cross sectionally the textured reflective surface of the back reflector comprises peaks, valleys and inclined portions connecting the peaks and valleys, and wherein major surfaces of at least some of the inclined portions form an angle α of from about 25-35 degrees with the plane and/or rear surface of the rear glass substrate.

7. The photovoltaic device of claim 1, wherein viewed cross sectionally the textured reflective surface of the back reflector comprises peaks, valleys and inclined portions connecting the peaks and valleys, and wherein major surfaces of at least some of the inclined portions form an angle α of from about 25-30 degrees with the plane and/or rear surface of the rear glass substrate.

8. The photovoltaic device of claim 1, wherein a pattern of the textured reflective surface of the back reflector has a periodicity of from about 100 μm to 1 mm.

9. The photovoltaic device of claim 1, wherein the semiconductor film comprises one or more layers comprising amorphous silicon.

10. The photovoltaic device of claim 1, wherein the polymer inclusive adhesive layer has a refractive index (n) of from about 1.9 to 2.1, and wherein the back contact comprises a transparent conductive oxide.

11. The photovoltaic device of claim 1, wherein the substantially transparent front electrode comprises, moving away from the front glass substrate toward the semiconductor film, at least a first substantially transparent conductive substantially metallic infrared (IR) reflecting layer comprising silver and/or gold, and a first transparent conductive oxide (TCO) film located between at least the IR reflecting layer and the semiconductor film.

12. The photovoltaic device of claim 11, wherein the first TCO film comprises one or more of zinc oxide, zinc aluminum oxide, tin oxide, indium-tin-oxide, and indium zinc oxide.

13. The photovoltaic device of claim 11, wherein the substantially transparent front electrode further comprises a second substantially transparent conductive substantially metallic infrared (IR) reflecting layer comprising silver and/or gold, and wherein the first transparent conductive oxide (TCO) film is located between at least said first and second IR reflecting layers.

14. The photovoltaic device of claim 13, wherein the first and second IR reflecting layers each comprise silver.

15. The photovoltaic device of claim 13, wherein the front electrode further comprises a second TCO film which is provided between at least the second IR reflecting layer and the semiconductor film.

16. The photovoltaic device of claim 11, further comprising a dielectric layer having a refractive index of from about 1.6 to 2.0 located between the front glass substrate and the front electrode.

17. The photovoltaic device of claim 11, wherein the first IR reflecting layer is from about 3 to 12 nm thick, and the first TCO film is from about 40 to 130 nm thick.

18. The photovoltaic device of claim 1, wherein the front glass substrate and the front electrode taken together have a transmission of at least about 80% in at least a substantial part of a wavelength range of from about 450-600 nm.

19. The photovoltaic device of claim 1, wherein the front glass substrate and front electrode taken together have an IR reflectance of at least about 45% in at least a substantial part of an IR wavelength range of from about 1400-2300 nm.

20. A photovoltaic device comprising:
a front substrate and a rear substrate;
an electrically conductive and substantially transparent front electrode;
an active semiconductor film located so that the front electrode is provided between at least the semiconductor film and the front substrate;
a back reflector formed on a textured surface of the rear substrate, the back reflector having a textured reflective surface and being located between at least the rear substrate and the semiconductor film; and
wherein the back reflector is laminated to and electrically insulated from at least the semiconductor film.

21. The photovoltaic device of claim 20, wherein the back reflector is electrically insulated from a back contact of the photovoltaic device via at least a polymer inclusive adhesive layer that has a refractive index (n) of from about 1.9 to 2.1.

22. The photovoltaic device of claim 20, wherein the textured reflective surface of the back reflector comprises peaks, valleys and inclined portions connecting the peaks and valleys, and wherein major surfaces of at least some of the inclined portions form an angle α of at least about 25 degrees with the plane and/or rear surface of the rear substrate.

23. The photovoltaic device of claim 20, wherein viewed cross sectionally the textured reflective surface of the back reflector comprises peaks, valleys and inclined portions connecting the peaks and valleys, and wherein major surfaces of at least some of the inclined portions form an angle α of from about 25-35 degrees with the plane and/or rear surface of the rear substrate.

24. The photovoltaic device of claim 20, wherein a pattern of the textured reflective surface of the back reflector has a periodicity of from about 100 μm to 1 mm.
